(19) United States
(12) Patent Application Publication
(10) Pub. No.: US 2003/0217835 A1
(43) Pub. Date: Nov. 27, 2003

(54) CPU heat sink fastener

(76) Inventor: Ming-Long Lee, Taipei (TW)

Correspondence Address: BIRCH STEWART KOLASCH & BIRCH, PO BOX 747, FALLS CHURCH, VA, 22040-0747, US

(21) Appl. No.: 10/152,041

(22) Filed: May 22, 2002

(51) Int. Cl. F28F 7/00; H05K 7/20; H01L 23/34

(52) U.S. Cl. 165/80.3; 361/704; 257/718; 257/719

(57) ABSTRACT

A CPU heat sink fastener includes several fasteners with press button on top and a tenor on bottom. After the fastener passes through the heat sink, it applies an elastic part as pressure mechanism to fix the fastener on the fixing hole of the circuitry board. A stable plate with several holding cylinders; each of the fasteners is placed inside one cylinder; an elastic part is under the press button. Two stretch plates with fixing through hole are located in the proper position in the heat sink. The heat sink is on right top of the CPU; the stable plate is on right top of the heat sink to make the holding cylinder faces directly with the stretch plate. Users can push the press button of the fastener and make the tenor pass through the through hole and fix firmly on the fixing through hole of the circuitry board.

### BACKGROUND OF THE INVENTION

I. Field of the Invention

This invention relates generally to a CPU heat sink fastener and, more specifically to a CPU heat sink that applies the push button fastener mechanism for a faster and easy installation method, and stronger structure for more stable joint.

II. Description of the Prior Art

Heretofore, it is known that a CPU generates lots of heat while it is running, the efficiency of heat dissipation of a CPU relates to the life of a computer and its stability. The structure of most of the known heat sinks mainly have a metal body (most of them are aluminum), and have fasteners to fix the heat sink and CPU together. Most of the fasteners are metal clips, the metal clip type is not so easy to install. The other know mechanism is the press button type as shown in FIG. 4 and FIG. 5, it has two or more fasteners 60 with a shank 61, a press button 63 on top, a tenon 62 on bottom and a spring 70 in the middle; a heat sink 80 in plate shape with wings on top, and a plurality of through holes 801 on proper locations; the heat sink 80 is on top of the CPU 81. The fastener 60 with spring 70 passes through the through hole 801 of the heat sink 80 and the fixing hole 820 of the circuitry board 82 with the tenon 62, the spring 70 is pressed between press button 63 and heat sink 80 to stable the whole structure.

Although the prior art described above is very convenient, it still has disadvantages, as shown in FIG. 5: the through hole 801 of the heat sink 80 and the fixing hole 820 of the circuitry board 82 must be larger than the tenon 62 of the fastener 60 to have the fastener 60 fixed in the fixing hole 820 and the through hole 801. When the fastener 60 is pushed in, it might swing to make the connection not so stable, the fasteners 60 might also fall off under vibration.

Moreover, the shank 61 of the fastener 60 and the through hole 801 of the heat sink 80 do not have a proper orientation mechanism, the through hole 801 is easily be enlarged or even broken.

### SUMMARY OF THE INVENTION

It is therefore a primary object of the invention to provide a CPU heat sink fastener compromising several fasteners with press button on top and a tenor on bottom. After the fastener passes through the heat sink, it applies an elastic part as pressure mechanism to fix the fastener on the fixing hole of the circuitry board. The major feature is: a stable plate with several holding cylinders; each of the fasteners is placed inside one cylinder; an elastic part is under the press button. Two stretch plates with fixing through hole are located in the proper position in the heat sink. The heat sink is on right top of the CPU; the stable plate is on right top of the heat sink to make the holding cylinder faces directly with the stretch plate. Users can push the press button of the fastener and make the tenor pass through the through hole and fix firmly on the fixing through hole of the circuitry board.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is an exploded drawing of the structure of the present invention;

FIG. 2 is a cross-section view drawing of the assembled present invention;

FIG. 3 is a cross-sectional view drawing of an exemplary embodiment of the present invention;

FIG. 4 is an external view drawing of the prior art;

FIG. 5 is a cross-section view drawing of the prior art.

### DESCRIPTION OF THE PREFERRED EMBODIMENT

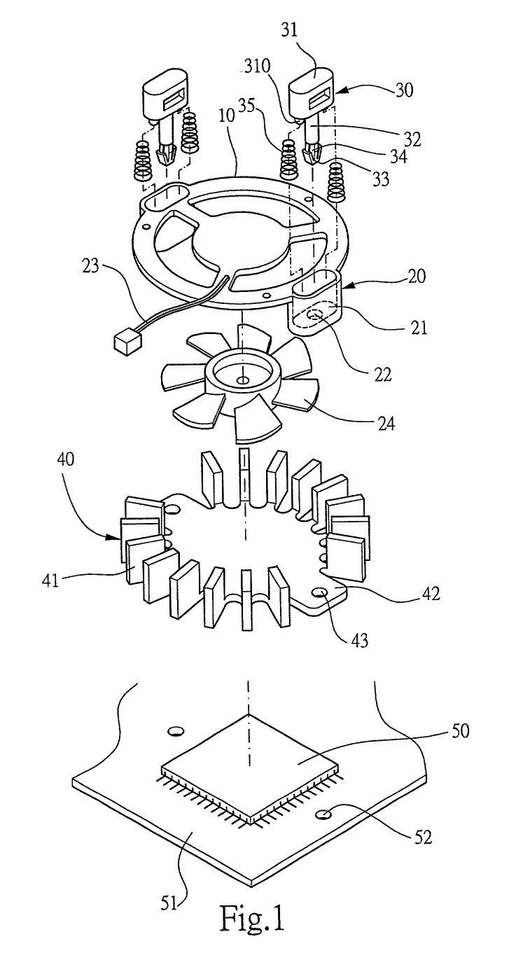

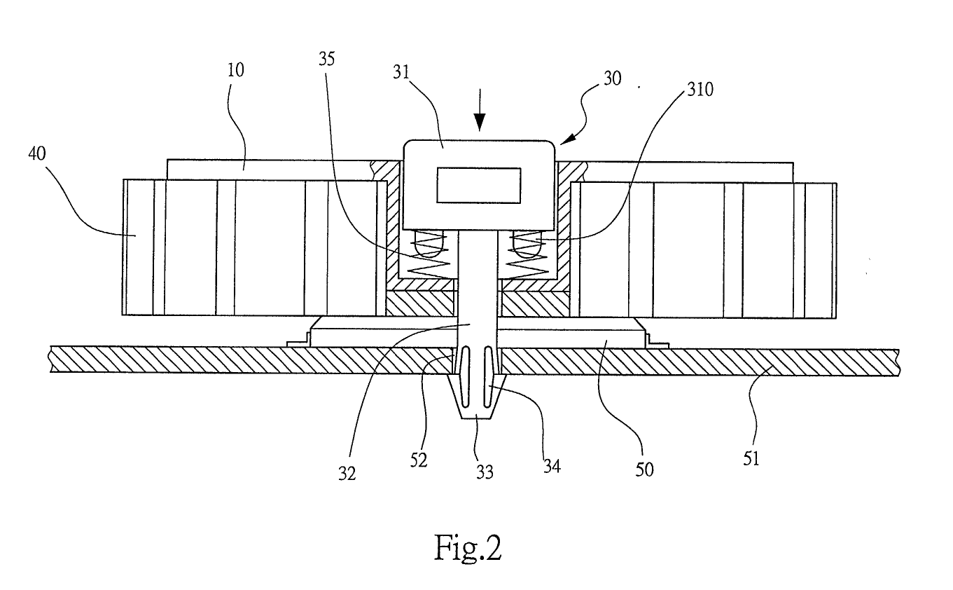

Referring to FIG. 1 and FIG. 2, the present invention is composed of two or more fastener 30, a stable plate 10 with two holding cylinder 20 to fasten a heat sink 40 to the CPU 50 on the circuit board 51. The stable plate 10 has several holes to reduce the weight, a circuitry 23 is on the center of the stable plate 10 connect to a fan 24, several holding cylinder 20 are on the circumference of the stable plate 10; a through hole 22 is on the bottom plate 21 of each holding cylinder 20.

The fastener 30 consists of a shank 32, a oval push button 31 on top; a tip 310 each is on both end of the oval push button 31, an elastic part 35 is connected to each of the tip 310. An arrow shape tenon 33 is on the bottom of the shank 32; a pressure crevice 34 is on the center of the tenon 33 to have fastener 30 fits inside the holding cylinder 20, also have the shank 32 passes through the through hole 22 of the bottom plate 21, and have the elastic part 35 located between the oval push button 31 and the bottom plate 21.

A plurality of wing 41 surround the heat sink 40, two stretch plate 42 with fixing through hole 43 are located in the proper location. The heat sink 40 is on right top of the CPU 50, the stable plate 10 is on top of the heat sink 40; the holding cylinder 20 faces stretch plate 42, users can press the oval push button 31 of the fastener 30 to have the tenon passes through the fixing through hole 43 and fixed on the fixing hole 52 of the circuitry board 51.

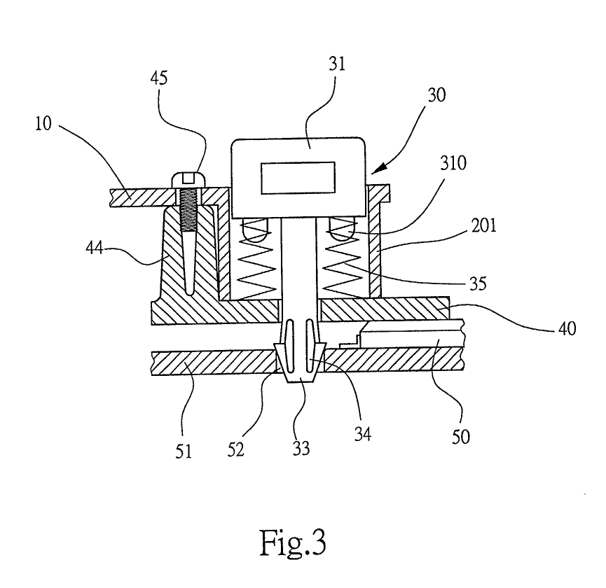

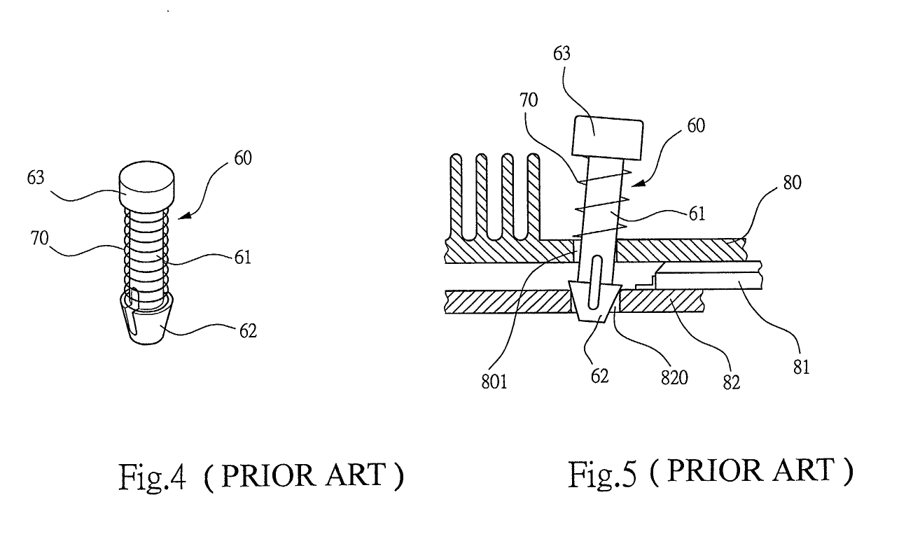

Another application example, referring to FIG. 3, a holding cylinder 201 without bottom plate; a screw holder 44 is located beside the stretch plate 42 of the heat sink 40, to have a screw 45 passes through heat sink 40 and fixed on the screw holder 44 to achieve a stronger joint structure.

Based on above structure, the present invention has following advantages:

1. The fastener fits in the holding cylinder; the shank will not swing to achieve the better fixing effect.

2. Two elastic parts to offer better fixing strength.

3. Cooling fan is in the center of the stable plate for better cooling effect, the stable plate has a plurality of holes for lighter weight.

While a preferred embodiment of the invention has been shown and described in detail, it will be readily understood and appreciated that numerous omissions, changes and additions may be made without departing from the spirit and scope of the invention.

What is claimed is:

1. A CPU heat sink fastener comprising:
at least two fasteners each with an oval push button on top, and a shank with an arrow shape tenon on the bottom; and
an elastic part located in said shank,
said shank passes through heat sink and said tenon fastens on the circuitry board, said elastic part presses and fixes said fastener;
wherein the improvement is characterized by:
a stable plate with several holding cylinders with a through hole on a bottom plate, said holding cylinders located on the circumference of said stable plate;
two tips located on both end of said oval push button, each of said tip connects to an elastic part to have said shank passes through said through hole of said bottom plate and have said elastic part sited between said oval push button and circuitry board;
two stretch plates with fixing through hole each located on the heat sink, heat sink locates on right top of the CPU, said stable plate locates on right top of said heat sink to face said stretch hole, push the oval push button have said tenon pass through said through hole and fasten said tenon on the fixing through hole of the circuitry board.

2. The CPU heat sink fastener recited in claim 1, wherein said holding cylinder is bottomless.

3. The CPU heat sink fastener recited in claim 1, wherein a screw holder located beside said stretch plate.

4. The CPU heat sink fastener recited in claim 1, wherein said stable plate has a plurality of holes.

5. The CPU heat sink fastener recited in claim 1, wherein said stable plate equipped with a fan on center for better cooling effect.

6. The CPU heat sink fastener recited in claim 1, wherein said holding cylinder's cross-section is in long elliptical shape.

7. The CPU heat sink fastener recited in claim 1, wherein said push button is in long elliptical shape.
